(19) United States
(12) Patent Application Publication
(10) Pub. No.: US 2026/0066392 A1
(43) Pub. Date: Mar. 5, 2026

(54) COOLANT MODULE AND THERMAL MANAGEMENT SYSTEM INCLUDING THE SAME

(71) Applicant: Hanon Systems, Daejeon (KR)

(72) Inventors: Jungbum CHOI, Daejeon (KR); Hyun Woong SHIN, Daejeon (KR); Shin-Won YUN, Daejeon (KR); Min Ho JANG, Daejeon (KR); Seong Woo JEONG, Daejeon (KR); Jeong Wan HAN, Daejeon (KR)

(73) Assignee: Hanon Systems, Daejeon (KR)

(21) Appl. No.: 19/311,359

(22) Filed: Aug. 27, 2025

(30) Foreign Application Priority Data
Aug. 30, 2024 (KR) 10-2024-0117349

(51) Int. Cl. H01M 10/6568; B60K 1/00; B60K 1/04; H01M 10/613; H01M 10/625; H05K 7/20

(52) U.S. Cl. CPC H01M 10/6568; B60K 1/04; H01M 10/613; H01M 10/625; B60K 2001/005; H01M 2220/20; H05K 7/20936

(57) ABSTRACT

A coolant module and a thermal management system including the same are disclosed. The coolant module includes a reservoir tank configured to store a coolant, a valve coupled to a lower side of the reservoir tank and configured to receive the coolant from the reservoir tank and determine a flow direction of the coolant, a manifold plate having a plurality of flow paths in which the coolant flows, and a pump connected to any one of the plurality of flow paths, the pump being configured to transfer the coolant to an external component, in which the valve is coupled to an upper surface of the manifold plate, the pump is provided as a plurality of pumps coupled to a lower surface of the manifold plate, and the coolant discharged from the valve flows along one flow path selected from the plurality of flow paths formed in the manifold plate.

### CROSS REFERENCE TO RELATED APPLICATION

The present application claims priority to Korean Patent Application No. 10-2024-0117349, filed on Aug. 30, 2024, the entire contents of which are incorporated herein for all purposes by this reference.

### BACKGROUND OF THE DISCLOSURE

### Field of the Disclosure

The present disclosure relates to a coolant module and a thermal management system including the same.

### Description of the Related Art

Unlike internal combustion engine vehicles, environmentally-friendly vehicles, such as hybrid electric vehicles and electric vehicles, are equipped with various electronic components such as batteries, motors, and inverters. These components generate a large amount of heat while operating, and the amounts and properties of heat generated from the components are different. In order to effectively manage the amounts and properties of heat, the environmentally-friendly vehicle requires a cooling system that is more precise and complex than that of the internal combustion engine vehicle.

The cooling system of the environmentally-friendly vehicle has a much more complex structure in comparison with the internal combustion engine vehicle and is required to use multiple cooling loops and be equipped with a precise temperature control system to cool various components. However, there is a problem in that the complexity increases the number of components of a coolant module, complicates a manufacturing process, and increases costs. In addition, the environmentally-friendly vehicle is limited in a space of an engine room because the environmentally-friendly vehicle needs to be equipped with a battery. The limitation of the space of the engine room makes it significantly difficult to design and dispose the cooling system.

Because the environmentally-friendly vehicle requires the complex cooling system in comparison with the internal combustion engine vehicle, as described above, there is a problem in that the number of components of the coolant module increases, the increase in number of components increases a likelihood of the occurrence of a breakdown, the manufacturing process is complicated, and the costs increase. In order to solve the above-mentioned problem, the system is required to be simplified.

### DOCUMENT OF RELATED ART

(Patent Document 1) Korean Patent Application Laid-Open No. 10-2023-0135780 (published on Sep. 26, 2023)

### SUMMARY OF THE DISCLOSURE

The present disclosure is proposed to solve these problems and aims to provide a coolant module capable of improving priming water supply performance by naturally forming a head difference from a reservoir tank to a pump.

The present disclosure also aims to provide a coolant module capable of being efficiently disposed in a limited layout.

The present disclosure also aims to provide a coolant module with improved convenience in mounting external components.

The present disclosure also aims to provide a simplified thermal management system.

Technical problems of the present disclosure are not limited to the aforementioned technical problems, and other technical problems, which are not mentioned above, may be clearly understood by those skilled in the art from the following descriptions.

The present disclosure provides a coolant module including: a reservoir tank configured to store a coolant; a valve coupled to a lower side of the reservoir tank and configured to receive the coolant from the reservoir tank and determine a flow direction of the coolant; a manifold plate having therein a plurality of flow paths in which the coolant flows; and a pump connected to any one of the plurality of flow paths formed in the manifold plate, the pump being configured to transfer the coolant to an external component, in which the valve is coupled to an upper surface of the manifold plate, in which the pump is provided as a plurality of pumps coupled to a lower surface of the manifold plate, and in which the coolant discharged from the valve flows along one flow path selected from the plurality of flow paths formed in the manifold plate.

The valve may include: a valve cylinder; an actuator configured to operate the valve cylinder; and a valve housing configured to accommodate the valve cylinder and communicate with the reservoir tank and the manifold plate, the valve housing may include: an upper port formed to be directed upward; and a plurality of lower ports formed to be directed downward, the upper port may communicate with a coolant discharge port of the reservoir tank, and the plurality of lower ports may respectively communicate with the plurality of flow paths formed in the manifold plate.

The plurality of lower ports may be formed such that entrance/exit surfaces face the upper surface of the manifold plate.

The plurality of lower ports may be grouped into a first lower port group formed to be biased toward a left side of the valve housing, and a second lower port group formed to be biased toward a right side of the valve housing, and the manifold plate may include: a first plate configured to face the entrance/exit surfaces of the first lower port group; and a second plate configured to face the entrance/exit surfaces of the second lower port group.

A gasket may be provided between the valve housing and the upper surface of the manifold plate.

The valve may be configured as a ten-way valve, and the valve housing may have one upper port and nine lower ports.

The pump may be provided as a plurality of pumps, and the pumps may communicate with any one of the plurality of flow paths formed in the manifold plate.

The manifold plate may include: an upper interface provided on the upper surface thereof; a lower interface provided on the lower surface thereof; and a lateral interface provided on a lateral surface thereof, the upper interface may allow the valve and the plurality of flow paths formed in the manifold plate to communicate with one another, the lower interface may allow the pump and any one of the plurality of flow paths formed in the manifold plate to communicate with each other, and the lateral interface may allow the external component and any one of the plurality of flow paths formed in the manifold plate to communicate with each other.

The lateral interface may include a connection pipe protruding in a direction parallel to a flat surface of the manifold plate.

The present disclosure provides a thermal management system, which is installed in a vehicle having a power electric module (PE module) and a battery module, the thermal management system including: a reservoir tank configured to store a coolant; a valve coupled to a lower side of the reservoir tank and configured to receive the coolant from the reservoir tank and determine a flow direction of the coolant; a manifold plate having therein a plurality of flow paths in which the coolant flows; a first pump connected to any one of the plurality of flow paths formed in the manifold plate, the first pump being configured to transfer the coolant to the battery module; and a second pump connected to another of the plurality of flow paths formed in the manifold plate, the second pump being configured to transfer the coolant to the PE module, in which the valve is coupled to an upper surface of the manifold plate, in which the first pump and the second pump are coupled to a lower surface of the manifold plate, and in which the coolant discharged from the valve flows along one flow path selected from the plurality of flow paths formed in the manifold plate.

The coolant having passed through the PE module may be introduced back into the manifold plate.

The thermal management system may further include: a chiller connected directly to the manifold plate, in which the coolant having passed through the battery module flows in the chiller and then is introduced back into the manifold plate.

The manifold plate may include a lateral interface provided on a lateral surface thereof and connected directly to the chiller, and the lateral interface may allow the chiller and any one of the plurality of flow paths formed in the manifold plate to communicate with each other.

The thermal management system may further include: a condenser; and a third pump connected to another of the plurality of flow paths formed in the manifold plate, the third pump being configured to transfer the coolant to the condenser, in which the third pump is coupled to the lower surface of the manifold plate.

### BRIEF DESCRIPTION OF THE DRAWINGS

FIG. 1 is a front perspective view of a coolant module according to one example of the present disclosure.

FIG. 2 is a rear perspective view of FIG. 1.

FIG. 3 is an exploded perspective view of FIG. 1.

FIG. 4 is a front perspective view of a valve according to one example of the present disclosure.

FIG. 5 is a rear perspective view of the valve.

FIG. 6 is a perspective view of a manifold plate according to one example of the present disclosure.

FIG. 7 is a view illustrating that a coolant flowing along the manifold plate is introduced into a pump.

FIG. 8 is a schematic view of a thermal management system according to one example of the present disclosure.

FIG. 9 is an exploded perspective view of the thermal management system.

FIG. 10 is a view schematically illustrating a fluid circuit diagram of the thermal management system.

FIGS. 11 to 13 are views schematically illustrating a flow of the coolant transferred by the pump.

### DETAILED DESCRIPTION OF THE DISCLOSURE

Hereinafter, the present disclosure will be described in detail with reference to the accompanying drawings. However, this is provided for illustrative purposes only, and the present disclosure is not limited to the exemplarily described specific embodiment.

A coolant module and a thermal management system including the same according to the present disclosure may be applied to vehicles such as hybrid electric vehicles and pure electric vehicles, applied to other heat exchange applications such as household or industrial applications, and used for some equipment required to be cooled and heated.

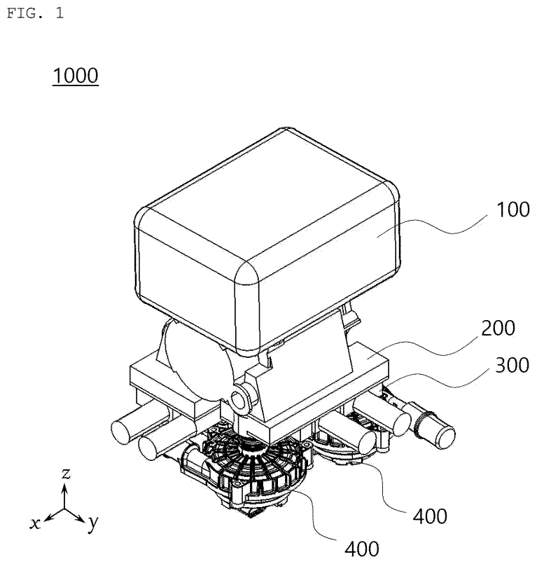

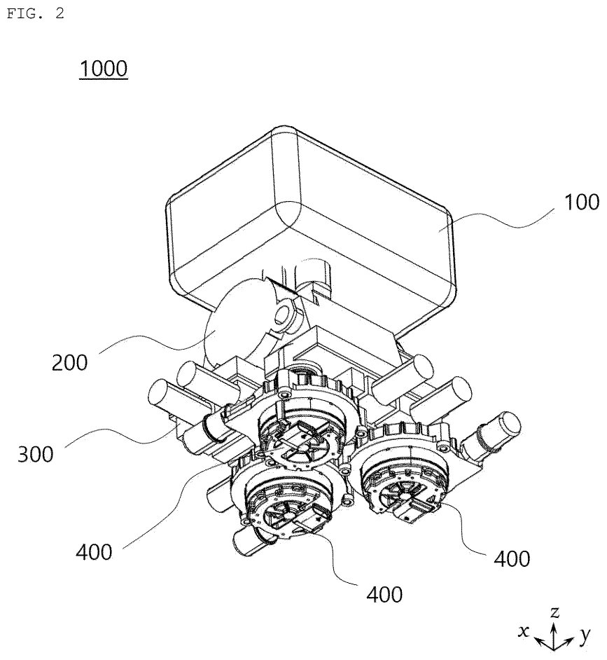

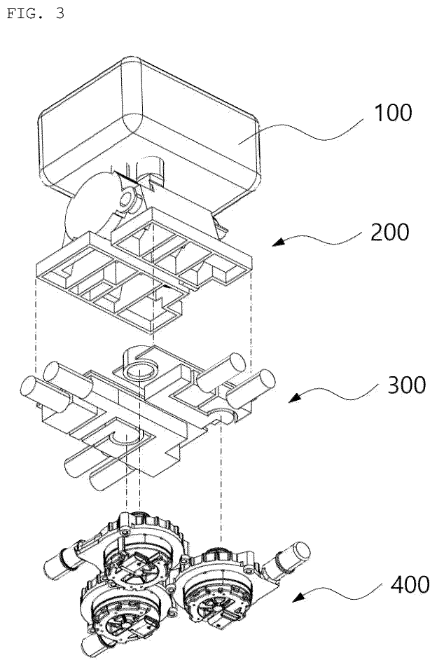

FIG. 1 is a front perspective view of a coolant module according to one example of the present disclosure, FIG. 2 is a rear perspective view of FIG. 1, and FIG. 3 is an exploded perspective view of FIG. 1. Directions will be defined with reference to FIGS. 1 to 2 to more specifically describe the present disclosure. An x-axis direction is referred to as a longitudinal direction, a y-axis direction perpendicular to the longitudinal direction is referred to as a width direction, and a z-axis direction perpendicular to the longitudinal direction and the width direction is referred to as a height direction.

According to one example of the present disclosure, a coolant module 1000 may include a reservoir tank 100 configured to store a coolant, a valve 200 coupled to a lower side of the reservoir tank 100, receive the coolant from the reservoir tank 100, and determine a flow direction of the coolant, a manifold plate 300 having a plurality of flow paths in which the coolant flows, and a pump 400 connected to any one of the plurality of flow paths formed in the manifold plate 300, the pump 400 being configured to transfer the coolant to an external component.

Specifically, as illustrated in FIG. 3, the valve 200 is coupled to an upper surface of the manifold plate 300, and the coolant discharged from the valve 200 may flow to one flow path selected from the plurality of flow paths formed in the manifold plate 300. In addition, the pump 400 may be coupled to a lower surface of the manifold plate 300, and at least a part of the coolant, which flows along the flow path formed in the manifold plate 300, may be transferred to the external component by the pump 400.

That is, the coolant module 1000 according to one example of the present disclosure may have a structure in which the pump 400, the manifold plate 300, the valve 200, and the reservoir tank 100 are sequentially stacked in the height direction (z-axis direction) from below. As described above, according to the present disclosure, the reservoir tank 100 is disposed at an uppermost end of the coolant module, and the pump 400 is disposed at a lowermost end of the coolant module, such that a head difference from the reservoir tank to the pump may be naturally formed, thereby improving priming water supply performance. Further, the pump 400 corresponds to a vertical-axis pump having a main shaft disposed in a direction perpendicular to a horizontal plane (x-y plane), thereby improving coolant transfer efficiency.

In addition, because the pump, the manifold plate, the valve, and the reservoir tank are sequentially stacked in the coolant module 1000, an area occupied by the pump, the manifold plate, the valve, and the reservoir tank in comparison with a case in which the components are disposed on the same plane, such that the coolant module may be efficiently disposed in a limited layout.

Meanwhile, the plurality of flow paths, in which the fluid may flow, may be formed in the manifold plate 300, and the manifold plate 300 may be provided in the form of a plate having a predetermined thickness. The manifold plate 300 may be configured as a plate having an approximately rectangular shape corresponding to a shape of a lower surface of a valve housing 210.

Hereinafter, the reservoir tank 100 will be described. The reservoir tank 100 may have therein a predetermined space and store the coolant. The reservoir tank 100 may supply the coolant to other devices depending on operating modes of a cooling system and control a flow rate of the coolant in case that the coolant is insufficient or excessive.

As illustrated in FIG. 1, the reservoir tank 100 may have an approximately rectangular parallelepiped shape, and this shape may be advantageous in efficiently disposing the coolant module in a narrow, limited layout in the vehicle.

A coolant discharge port, through which the coolant is discharged, may be formed in a lower surface of the reservoir tank 100. The coolant discharge port may communicate with an upper port 230 of the valve housing 210 to be described below, and the coolant stored in the reservoir tank 100 may be introduced into the valve 200 through the coolant discharge port and the upper port 230.

Hereinafter, the pump 400 will be described. The pump 400 may correspond to a device that circulates the coolant in the coolant module to the cooling system of the vehicle. The pump 400 may be used without limitation as long as the pump may transfer the coolant. In the case of an electric vehicle, an electric water pump (EWP) configured to be operated by an electric motor may be used as the pump.

The pump may be provided as a plurality of pumps 410, 420, and 430, and the pumps 410, 420, and 430 may each communicate with any one of the plurality of flow paths formed in the manifold plate 300. The pumps 410, 420, and 430 may be installed in devices that require the coolant. The pumps 410, 420, and 430 may circulate the coolant in the corresponding devices, such that various components in the vehicle may be cooled.

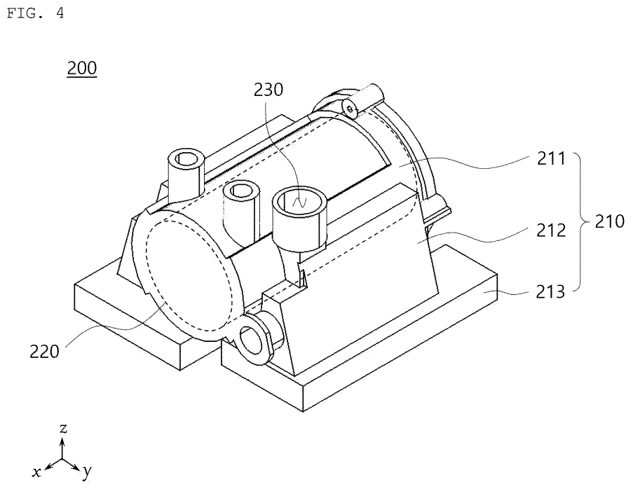

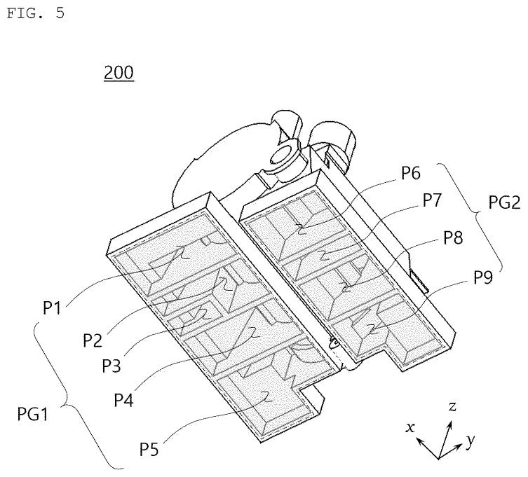

Hereinafter, the valve 200 will be described with reference to FIGS. 4 and 5. FIG. 4 is a front perspective view of the valve 200, and FIG. 5 is a rear perspective view of the valve 200.

According to one example of the present disclosure, the valve 200 may include a valve cylinder 220, an actuator 250 configured to operate the valve cylinder, and the valve housing 210 configured to accommodate the valve cylinder 220 and communicate with the reservoir tank 100 and the manifold plate 300.

The valve cylinder 220 may have a plurality of ports formed in a circumferential direction directed from a central axis. When the valve cylinder 220 rotates about the central axis, an inlet/outlet port for the coolant may be determined, and a flow direction may be adjusted. The valve housing 210 may have ports corresponding to the ports of the valve cylinder 220. The valve cylinder 220 and the valve housing 210 may be organically coupled to each other, thereby implementing various cooling operation modes.

The valve housing 210 may include the upper port 230 formed to be directed upward, and a plurality of lower ports P1, P2, . . . , and P9 formed to be directed downward. The upper port 230 may communicate with the coolant discharge port of the reservoir tank 100, and the plurality of lower ports may communicate with the plurality of flow paths formed in the manifold plate 300. As described above, the valve 200 may include the plurality of ports to adjust the flow direction of the coolant and switch the operating modes of the cooling system by switching the connection between the ports, as necessary.

The flow paths may be formed in the manifold plate 300 and correspond to the plurality of lower ports P1, . . . , and P9 in a one-to-one manner. The coolant, which is discharged through one of the lower ports of the valve housing 210, may pass through the flow path disposed in the manifold plate 300 and corresponding to the corresponding lower port and then be transferred to the external component through the pump 400. A gasket may be provided between the valve housing 210 and the upper surface of the manifold plate 300 and prevent a leak of the coolant between the valve 200 and the manifold plate 300.

Meanwhile, the plurality of lower ports may be formed such that entrance/exit surfaces (gray region in FIG. 5) face the upper surface of the manifold plate 300. Specifically, the valve housing 210 may include a cylinder part 211 having a cylindrical shape and configured to accommodate the valve cylinder 220, an inlet/outlet port part 213 configured to face the upper surface of the manifold plate 300 and define the entrance/exit surfaces of the lower ports P1, P2, . . . , and P9, and a connection part 212 extending downward from the cylinder part 211 and configured to allow the cylinder part 211 and the inlet/outlet port part 213 to communicate with each other. All the cylinder part 211, the connection part 212, and the inlet/outlet port part 213 may be integrated.

Specifically, the cylinder part 211 of the valve housing 210 may have a port configured to organically communicate with the port of the valve cylinder 220, and the connection part 212 may provide a flow path for the fluid introduced into the port of the cylinder part 211. The entrance/exit surfaces of the lower ports P1, P2, . . . , and P9 may be formed in a lower surface of the inlet/outlet port part 213 and allow the manifold plate 300 and the valve housing 210 to communicate with each other. The lower surface of the inlet/outlet port part 213 and the upper surface of the manifold plate 300 may be assembled to face each other, such that the lower ports may communicate with the flow paths in the manifold plate 300.

Further, with reference to FIG. 5, the lower ports may be grouped into a first lower port group PG1 formed to be biased toward the left side of the valve housing 210, and a second lower port group PG2 formed to be biased toward the right side of the valve housing 210. The manifold plate 300 includes a first plate 310 configured to face the entrance/exit surfaces of the first lower port group PG1, and a second plate 320 configured to face the entrance/exit surfaces of the second lower port group PG2, and the first plate and the second plate may be individually assembled to the valve housing 210.

Meanwhile, the valve 200 may be configured as a ten-way valve having ten ports. Various combinations of the flow paths may be implemented by the ten ports. Specifically, the valve 200 may include one upper port 230 connected to the reservoir tank 100, and nine lower ports P1, . . . , and P9 connected to the manifold plate 300.

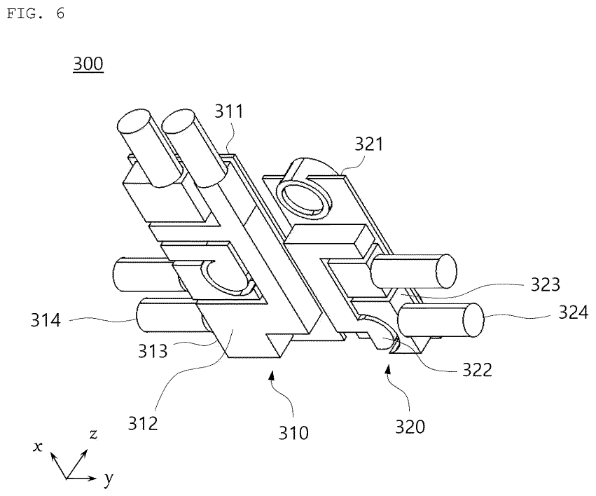

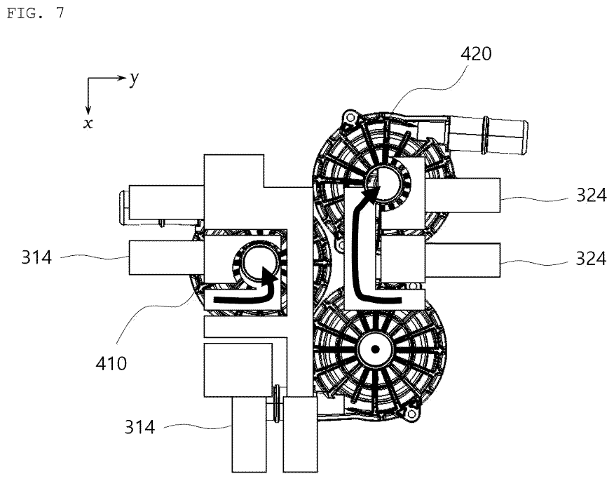

Hereinafter, the manifold plate 300 according to one example of the present disclosure will be described in detail with reference to FIGS. 6 and 7. FIG. 6 is a perspective view of the manifold plate 300 according to one example of the present disclosure, and FIG. 7 is a view illustrating that the coolant flowing along the manifold plate 300 is introduced into the pump.

The manifold plate 300 may have an approximately rectangular parallelepiped shape and have a plate-type shape in which a height is smaller than an area. The plurality of flow paths may be formed in the manifold plate 300. Various components may be mounted on interfaces of the manifold plate 300, thereby configuring various fluid circuits around the manifold plate 300.

Specifically, the manifold plate 300 may include upper interfaces 311 provided on the upper surface, lower interfaces 312 and 322 provided on the lower surface, and lateral interfaces 313 and 323 provided on a lateral surface.

The valve 200 may be mounted on the manifold plate 300 through the upper interfaces 311 and 321, and the valve 200 and the plurality of flow paths formed in the manifold plate 300 may communicate with one another. The pump 400 may be mounted on the manifold plate 300 through the lower interfaces 312 and 322, and the pump 400 and any one of the plurality of flow paths formed in the manifold plate 300 may communicate with each other. External components (a condenser, a PE module, a battery module, a heat exchanger, etc.) may be mounted on the manifold plate 300 through the lateral interfaces 313 and 323, and any one of the plurality of flow paths formed in the manifold plate 300 and the external components may communicate with one another.

FIG. 7 illustrates that any one flow path formed in the manifold plate 300 communicates with a pump 410 positioned at the left side based on the drawing to allow the coolant to flow, and another flow path communicates with a pump 420 positioned at the right side based on the drawing to allow the coolant to flow. As described above, the coolant flowing in the manifold plate 300 may be introduced into any one pump 400 and transferred to the external component.

Meanwhile, at least one connection pipe 314 or 324 may be provided on the lateral interfaces 313 and 323. The coolant module 1000 and the external component may be connected by the connection pipes 314 and 324. The connection pipes 314 and 324 may protrude in a direction parallel to a flat surface of the manifold plate 300. According to one example of the present disclosure, the external components may be easily mounted on the manifold plate 300 through the connection pipes 314 and 324 provided on the lateral interfaces, thereby improving manufacturing convenience. Further, the external components may be mounted without increasing an overall height of the coolant module 1000, thereby improving spatial efficiency.

In addition, according to one example of the present disclosure, the external component may be easily mounted on the coolant module 1000 by means of the manifold plate 300, thereby providing an advantage of flexibly expanding the system.

In addition, according to one example of the present disclosure, because the complex flow paths are provided in the manifold plate 300, components (hoses, pipes, couplings, etc.) for implementing the complex flow paths may be excluded, thereby providing an advantage of reducing a breakdown of a product, reducing costs, and improving manufacturing convenience. In addition, the valve and the pump are indirectly connected by the interfaces provided on the manifold plate 300, such that a head difference between the valve and the pump may occur, thereby providing an advantage of improving the priming water supply performance of the pump.

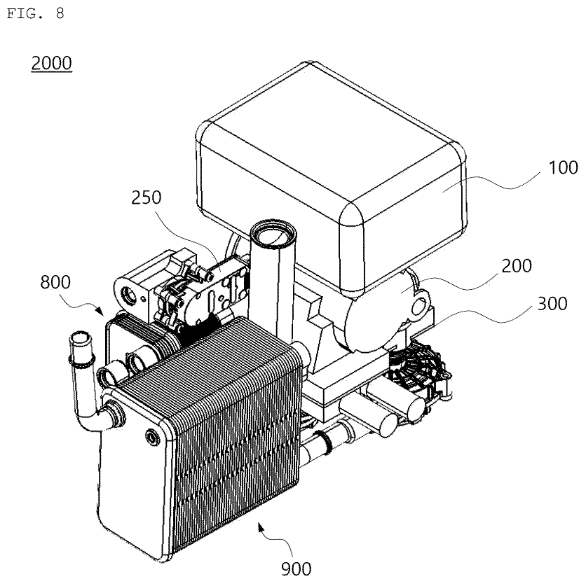

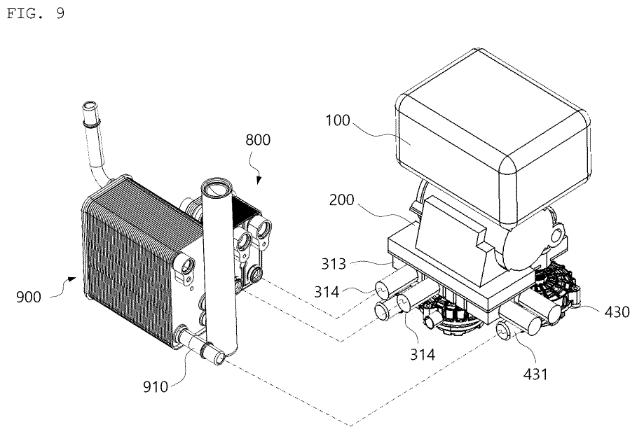

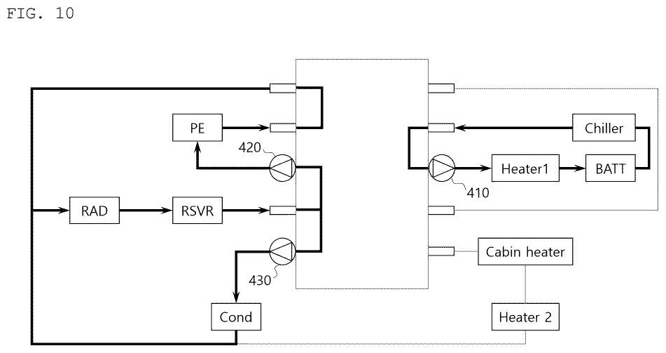

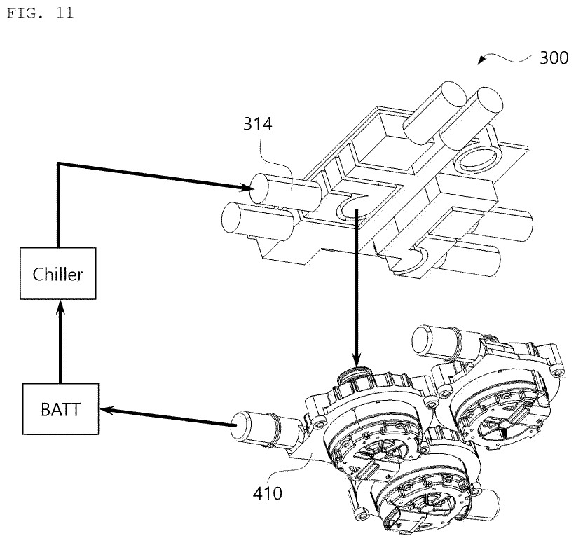

Hereinafter, a thermal management system 2000 according to one example of the present disclosure will be described with reference to FIGS. 8 to 13. FIG. 8 is a schematic view of the thermal management system 2000 according to one example of the present disclosure, FIG. 9 is an exploded perspective view of the thermal management system 2000, FIG. 10 is a view schematically illustrating a fluid circuit diagram of the thermal management system 2000, and FIGS. 11 to 13 are views schematically illustrating a flow of the coolant transferred by the pump.

The thermal management system 2000 according to one example of the present disclosure may be installed in a vehicle having a power electric module (PE module) and a battery module. The thermal management system 2000 may include the reservoir tank 100 configured to store the coolant, the valve 200 coupled to the lower side of the reservoir tank 100 and configured to receive the coolant from the reservoir tank 100 and determine the flow direction of the coolant, the manifold plate 300 having the plurality of flow paths in which the coolant flows, a first pump 410 connected to any one of the plurality of flow paths formed in the manifold plate 300, the first pump 410 being configured to transfer the coolant to the battery module, and a second pump 420 connected to another of the plurality of flow paths formed in the manifold plate 300, the second pump 420 being configured to transfer the coolant to the PE module.

The thermal management system 2000 may further include a chiller 800. The chiller 800 may be mounted on the manifold plate 300 through the lateral interface of the manifold plate 300. The lateral interface may allow the chiller 800 to communicate with any one of the plurality of flow paths formed in the manifold plate. In addition, the chiller 800 may be mounted through the connection pipes 314 and 324 provided on the lateral interfaces and communicate with any one of the plurality of flow paths, which are formed in the manifold plate 300, through the connection pipes.

Specifically, as illustrated in FIGS. 10 and 11, the coolant transferred through the first pump 410 may pass through a battery module BATT and be introduced back into the manifold plate. As described above, the chiller 800 may be connected directly to the connection pipe 314 of the manifold plate 300, and the coolant having passed through the battery module BATT may flow through the chiller 800 and then be introduced back into the manifold plate 300 through the connection pipe 314 through which the chiller 800 and the manifold plate 300 are directly connected.

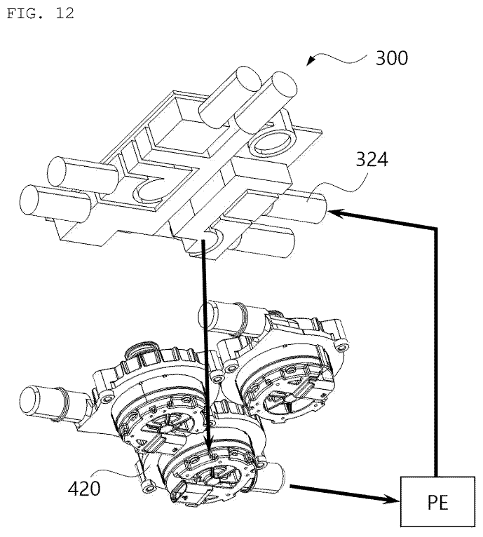

In addition, as illustrated in FIGS. 10 and 12, the coolant transferred by the second pump 420 may pass through the PE module and then be introduced back into the manifold plate 300.

Meanwhile, the thermal management system 2000 may further include a condenser 900 (Cond), and a third pump 430 connected to another of the plurality of flow paths formed in the manifold plate 300, the third pump 430 being configured to transfer the coolant to the condenser 900. In this case, like the first pump 410 and the second pump 420, the third pump 430 may be coupled to the lower surface of the manifold plate 300.

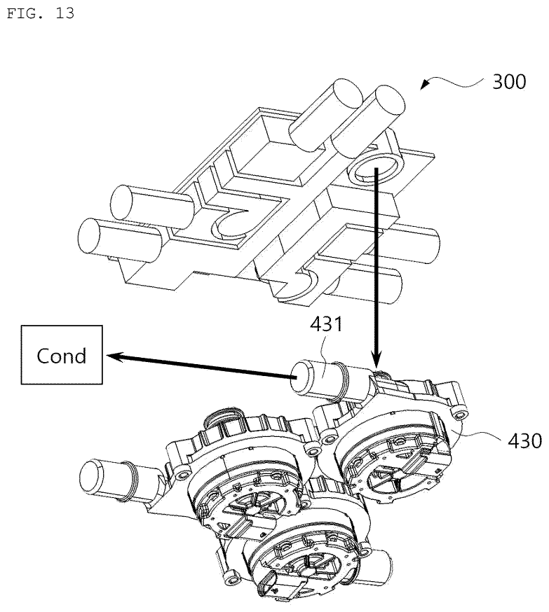

The condenser 900 may be connected directly to a discharge port 431 of the third pump 430. Specifically, as illustrated in FIGS. 10 and 13, the coolant transferred through the third pump 430 may pass through the condenser 900 and then be introduced back into the reservoir tank 100 (RSVR), such that the coolant may circulate in the thermal management system.

According to the embodiment of the present disclosure, the head difference from the reservoir tank to the pump may be naturally formed, thereby improving the priming water supply performance.

In addition, the coolant module may be efficiently disposed in a limited layout.

In addition, it is possible to improve convenience in mounting the external components.

In addition, the system may be simplified, thereby improving manufacturing convenience and reducing manufacturing costs.

The effects of the present disclosure are not limited to the above-mentioned effects, and other effects, which are not mentioned above, may be clearly understood by those skilled in the art from the present specification and the accompanying drawings.

While the embodiments of the present disclosure have been described with reference to the accompanying drawings, those skilled in the art will understand that the present disclosure may be carried out in any other specific form without changing the technical spirit or an essential feature thereof. Therefore, it should be understood that the above-described embodiments are illustrative in all aspects and do not limit the present disclosure.

### DESCRIPTION OF REFERENCE NUMERALS

1000: Coolant module
100: Reservoir tank
200: Valve
210: Valve housing
230: Upper port
P1, P2, . . . , P9: Lower port
PG1: First lower port group
PG2: Second lower port group
220: Valve cylinder
250: Actuator
300: Manifold plate
310: First plate
320: Second plate
311, 321: Upper interface
312, 322: Lower interface
313, 323: Lateral interface
314, 324: Connection pipe
400: Pump
410: First pump
420: Second pump
430: Third pump
800: Chiller
900: Condenser

What is claimed is:

1. A coolant module comprising:
a reservoir tank configured to store a coolant;
a valve coupled to a lower side of the reservoir tank and configured to receive the coolant from the reservoir tank and determine a flow direction of the coolant;
a manifold plate having therein a plurality of flow paths in which the coolant flows; and
a pump connected to any one of the plurality of flow paths formed in the manifold plate, the pump being configured to transfer the coolant to an external component,
wherein the valve is coupled to an upper surface of the manifold plate,
wherein the pump is provided as a plurality of pumps coupled to a lower surface of the manifold plate, and
wherein the coolant discharged from the valve flows along one flow path selected from the plurality of flow paths formed in the manifold plate.

2. The coolant module of claim 1, wherein the valve comprises:
a valve cylinder;
an actuator configured to operate the valve cylinder; and
a valve housing configured to accommodate the valve cylinder and communicate with the reservoir tank and the manifold plate,
wherein the valve housing comprises:
an upper port formed to be directed upward; and
a plurality of lower ports formed to be directed downward,
wherein the upper port communicates with a coolant discharge port of the reservoir tank, and
wherein the plurality of lower ports respectively communicate with the plurality of flow paths formed in the manifold plate.

3. The coolant module of claim 2, wherein the plurality of lower ports are formed such that entrance/exit surfaces face the upper surface of the manifold plate.

4. The coolant module of claim 3, wherein the plurality of lower ports are grouped into a first lower port group formed to be biased toward a left side of the valve housing, and a second lower port group formed to be biased toward a right side of the valve housing, and
wherein the manifold plate comprises:
a first plate configured to face the entrance/exit surfaces of the first lower port group; and
a second plate configured to face the entrance/exit surfaces of the second lower port group.

5. The coolant module of claim 2, wherein a gasket is provided between the valve housing and the upper surface of the manifold plate.

6. The coolant module of claim 2, wherein the valve is configured as a ten-way valve, and the valve housing has one upper port and nine lower ports.

7. The coolant module of claim 1, wherein the pump is provided as a plurality of pumps, and the pumps communicate with any one of the plurality of flow paths formed in the manifold plate.

8. The coolant module of claim 7, wherein the pump is a vertical-axis pump with the main shaft direction perpendicular to the horizontal plane.

9. The coolant module of claim 1, wherein the manifold plate comprises:
an upper interface provided on the upper surface thereof;
a lower interface provided on the lower surface thereof; and
a lateral interface provided on a lateral surface thereof,
wherein the upper interface allows the valve and the plurality of flow paths formed in the manifold plate to communicate with one another,
wherein the lower interface allows the pump and any one of the plurality of flow paths formed in the manifold plate to communicate with each other, and
wherein the lateral interface allows the external component and any one of the plurality of flow paths formed in the manifold plate to communicate with each other.

10. The coolant module of claim 9, wherein the lateral interface comprises a connection pipe protruding in a direction parallel to a flat surface of the manifold plate.

11. A thermal management system, which is installed in a vehicle having a power electric module (PE module) and a battery module, the thermal management system comprising:
a reservoir tank configured to store a coolant;
a valve coupled to a lower side of the reservoir tank and configured to receive the coolant from the reservoir tank and determine a flow direction of the coolant;
a manifold plate having therein a plurality of flow paths in which the coolant flows;
a first pump connected to any one of the plurality of flow paths formed in the manifold plate, the first pump being configured to transfer the coolant to the battery module; and
a second pump connected to another of the plurality of flow paths formed in the manifold plate, the second pump being configured to transfer the coolant to the PE module,
wherein the valve is coupled to an upper surface of the manifold plate,
wherein the first pump and the second pump are coupled to a lower surface of the manifold plate, and
wherein the coolant discharged from the valve flows along one flow path selected from the plurality of flow paths formed in the manifold plate.

12. The thermal management system of claim 11, wherein the coolant having passed through the PE module is introduced back into the manifold plate.

13. The thermal management system of claim 11, further comprising:
a chiller connected directly to the manifold plate,
wherein the coolant having passed through the battery module flows in the chiller and then is introduced back into the manifold plate.

14. The thermal management system of claim 13, wherein the manifold plate comprises a lateral interface provided on a lateral surface thereof and connected directly to the chiller, and the lateral interface allows the chiller and any one of the plurality of flow paths formed in the manifold plate to communicate with each other.

15. The thermal management system of claim 11, further comprising:
a condenser; and
a third pump connected to another of the plurality of flow paths formed in the manifold plate, the third pump being configured to transfer the coolant to the condenser,
wherein the third pump is coupled to the lower surface of the manifold plate.
